(19) United States
(12) Patent Application Publication
(10) Pub. No.: US 2013/0048050 A1
(43) Pub. Date: Feb. 28, 2013

(54) PHOTONIC ENERGY CONCENTRATORS BY WAY OF FOLDED MATERIAL

(71) Applicants: Karl S. Weibezahn, Corvallis, OR (US); Frank Bretl, Corvallis, OR (US)

(72) Inventors: Karl S. Weibezahn, Corvallis, OR (US); Frank Bretl, Corvallis, OR (US)

(21) Appl. No.: 13/215,421

(22) Filed: Aug. 23, 2011

(51) Int. Cl. H01L 31/052; B29D 11/00; G02B 5/10; H01L 31/18

(52) U.S. Cl. 136/246; 29/890.033; 264/2.7; 359/853

(57) ABSTRACT

Apparatus and methods related to solar energy are provided. A reflector array is formed from a sheet material. The reflector array includes light concentrators and hinge features. A reflective surface treatment is applied to at least some portions of the reflector array. The reflector array is folded from an initial configuration into an operable configuration by way of the hinges. Housing, framework, foam material or other supports maintain the operable configuration. Photovoltaic cells or other entities are disposed at respective target locations so as receive concentrated photonic energy by way of the light concentrators.

### STATEMENT OF GOVERNMENT INTEREST

The invention that is the subject of this patent application was made with Government support under Subcontract No. CW135971, under Prime Contract No. HR0011-07-9-0005, through the Defense Advanced Research Projects Agency (DARPA). The Government has certain rights in this invention.

### BACKGROUND

Photovoltaic cells are solid-state devices that directly convert incident photonic energy, such as sunlight, into electrical energy. Other types of systems heat or boil water or other fluid media using solar radiation. Improvements to such devices and related systems are continuously sought after. The present teachings address the foregoing concerns.

### BRIEF DESCRIPTION OF THE DRAWINGS

The present embodiments will now be described, by way of example, with reference to the accompanying drawings, in which:

FIG. 1A depicts an isometric-like view of a reflector array in an initial configuration according to one example of the present teachings;

FIG. 1B depicts an isometric-like view of the reflector array of FIG. 1A in an operable configuration:

FIG. 2A depicts an elevation view of a reflector array in an initial configuration;

FIG. 2B depicts an elevation view of the reflector array of FIG. 2A in an operable configuration;

FIG. 3 depicts an elevation section view of a solar device according to the present teachings;

FIG. 4 depicts a block diagram of a system according to the present teachings;

FIG. 5 depicts a flow diagram of a method according to the present teachings;

### DETAILED DESCRIPTION

### Introduction

Apparatus and methods related to photonic energy are provided. An illustrative device includes a monolithic structure formed from a sheet material and defining at least one hinge and one or more light concentrators. The reflector array bears a reflective surface treatment or metalized film. The reflector array is formed in an initial, generally flattened configuration and is folded to define an operable configuration. The operable configuration is such that target areas defined by the respective light concentrators are coincident with predetermined locations or aspects of the reflector array.

A housing, a framework or structure, or foam material, or some combination of these, is/are disposed about the backside of the reflector array so as to maintain the operable configuration. Photovoltaic cells or other entities are disposed at the target locations. A transparent cover can be used to protect the reflector array and target entities against damage. Such devices can be used to derive electrical energy through direct conversion, heating or boiling of water or other heat transfer media, and so on.

In one example, a method includes forming a sheet material so as to define a reflector array. The reflector array is characterized by one or more hinges and a plurality of light concentrators. The method also includes folding the reflector array from an initial configuration to an operable configuration by way of the hinges. The method further includes supporting the reflector array in the operable configuration by way of a support structure.

In another example, a system includes a monolithic structure defining one or more hinges and a plurality of light concentrators. The monolithic structure is formed from a sheet material. The system also includes a reflective material supported by the monolithic structure, coincident with at least the light concentrators such that a solar array is defined. The system also includes a structure to support the solar array in an operable configuration. The operable configuration is characterized by a folding of the monolithic structure at the one or more hinges.

### First Illustrative Device

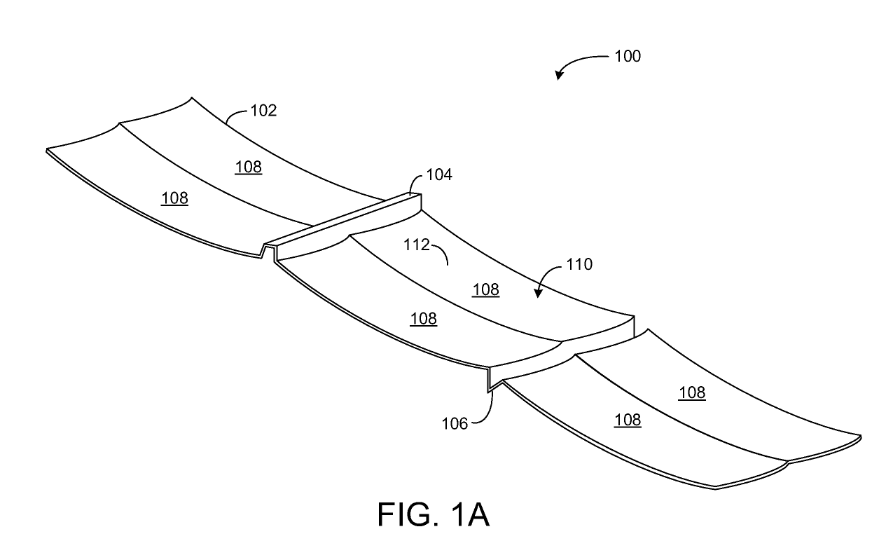

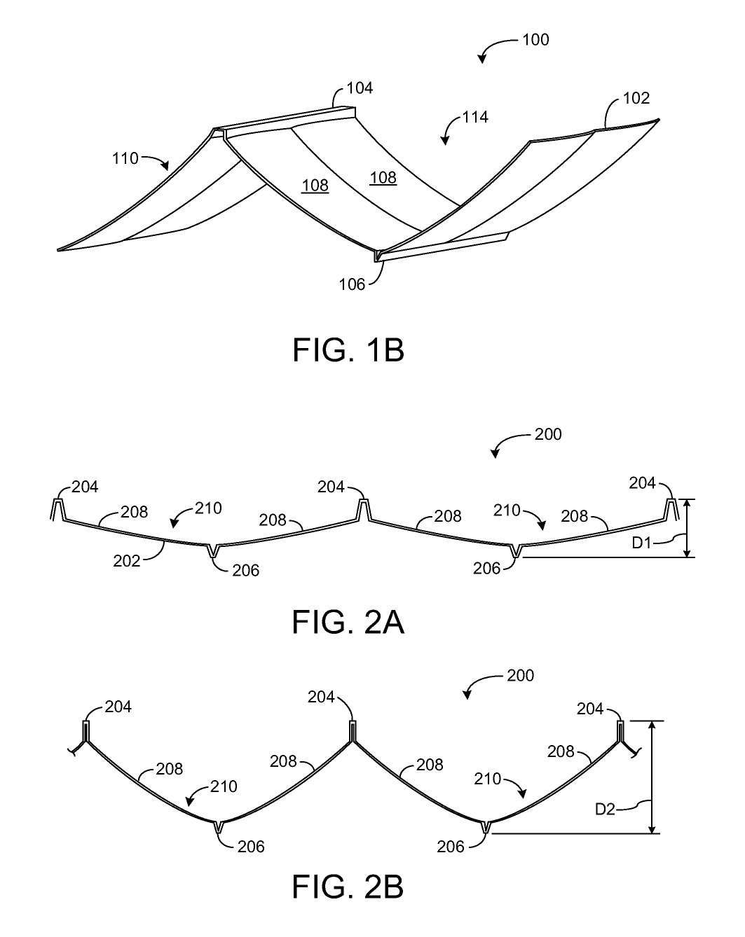

Reference is now directed to FIG. 1A, which depicts an isometric-like view of a reflector array 100. The reflector array 100 is illustrative and non-limiting in nature. Thus, other devices, apparatus and systems are contemplated by the present teachings.

The reflector array 100 includes a sheet material 102. The sheet material 102 can be formed from thermoplastic, plastic, and so on. The sheet material 102 is formed to define an upper hinge feature 104 and a lower hinge feature 106. The sheet material 102 is also formed to define a plurality of light concentrators 108. The device 100 can be formed by way of thermoforming the sheet material 102. In another example, the device 100 is formed by way of stamping the sheet material 102. The formed sheet material 102 defines a monolithic structure.

As depicted, the reflector array 100 includes one upper hinge 104 and one lower hinge 106 and six light concentrators 108 in the interest of clarity. However, other reflector arrays can also be defined and formed including any suitable numbers, or omitting particular ones, of the respective features 104, 106 and 108. For example, various reflector arrays can be defined having a single lower hinge (e.g., 106) and having no upper hinges, and so on. Other examples can also be defined. Thus, the present teachings contemplate reflector arrays of any suitable size and configuration.

A reflective material or surface treatment 110 is applied to or formed upon the sheet material 102, at least coincident with the respective light concentrators 108. Non-limiting examples of surface treatments 106 can be defined by or include one or more layers of aluminum, silver, silicon dioxide (SiO₂), titanium dioxide (TiO₂), niobium dioxide (NbO₂), or other suitable materials or compounds. In one example, the surface treatment 110 is defined by a layer of aluminum over-coated with a protective layer of silicon dioxide (SiO₂). Other combinations can also be used.

In another example, a reflective metalized film 110 is applied or bonded to the sheet material 102. A non-limiting example of such a metalized film 110 is Silver Reflective Film No. 690111, manufactured by Astra Products, Inc., and as available from Techplast Coated Products, Baldwin, N.Y., USA. Other suitable reflective films 110 can also be used.

Each light concentrator 108 is defined by a double parabolic or double semi-parabolic cross-sectional shape. The resulting dish-like surface contour 112 defines a spot-like target location or “focal point” for that respective light concentrator 108. In another example, each light concentrator (i.e., 108) is defined by a single parabolic or semi-parabolic cross-sectional shape such that an elongated strip-like target location is defined. Other surface contours can also be used. Each light concentrator 108 is configured to concentrate incident photonic energy (e.g., sunlight) onto a respective target location by virtue of the reflective surface treatment 110 and surface contour 112 thereof.

The reflector array 100 is in an initial configuration as depicted in FIG. 1A. This initial configuration is generally flattened and is incident to the formation process (i.e., thermoforming or stamping, and so on). The upper hinge 104 and the lower hinge 106 are in respectively open or “relaxed” states, not yet having been flexed or folded subsequent to the forming process.

Attention is now turned to FIG. 1B, which depicts the reflector array 100 folded into an operable configuration. The sheet material 102 has been folded along or by way of the upper hinge 104 and the lower hinge 106 such that a trough (or valley) 114 is defined by corresponding inward-facing light concentrators 108.

“Stretch marks” and other evidence of surface deformation are present when a plastic sheet is deep-drawn into a mold during a typical thermoforming process. The operable configuration of FIG. 1B, for example, would correspond to such a deep-drawn formation if it were manufactured in that way. A smooth parabolic surface contour is paramount to proper concentration of photonic energy (sunlight) on to a photovoltaic cell and other target.

Draw depth should therefore be minimized to eliminate or significantly reduce surface deformation and to prevent excessive stretching of the sheet material. The present teachings contemplate the formation of various reflector arrays based on an altered or “flattened” initial geometry (e.g., FIG. 1A) derived by a formation step, which is thereafter folded or manipulated along respective hinge features (e.g., 104 and 106) into an operable geometry (e.g., FIG. 1B). The operable configuration is then suitably supported to maintain the desired form-factor and orientation of the reflector array.

### Second Illustrative Device

Reference is now made to FIG. 2A, which depicts an end elevation view of a reflector array 200. The reflector array 200 is illustrative and non-limiting in nature. Thus, other devices, apparatus and systems are contemplated by the present teachings.

The reflector array 200 includes a sheet material 202 that has been formed by thermoforming, stamping or another suitable technique. In particular, the sheet material 202 defines respective upper hinges 204, respective lower hinges 206, and respective light concentrators 208 of the reflector array 200. The upper hinges 204, lower hinges 206 and light concentrators 208 are analogous to the elements 104, 106 and 108, respectively, as described above. The reflector array 200 further includes a reflective surface treatment or metalized film 210 born by the sheet material 202 and coincident (at least) with the light concentrators 208.

The reflector array 200 is in an initial configuration as depicted in FIG. 2A, essentially as formed by thermoforming, stamping, and so on. The initial configuration of the reflector array 200 is defined by an overall depth-wise dimension “D1”. In one example, the sheet material 202 is Copolyester No. MD-EK10R00 plastic, available from Klockner Pentaplast of America, Gordonsville, Va., USA, having a thickness of 1.0 millimeters, and thermoformed to define a reflector array 200 having a dimension D1 of 5.0 millimeters in the initial configuration. Other respective dimensions can also be used.

Attention is now turned to FIG. 2B, which depicts an end elevation view of the device 200 in an operable configuration. The operable configuration is established by folding (or manipulating) the sheet material 202 by way of the upper hinges 204 and the lower hinges 206. The operable configuration of the reflector array 200 is defined by an overall depth-wise dimension “D2”. In one example, the dimension D2 is about 40.0 millimeters. Other respective dimensions can also be used.

The area of a reflector array (e.g., 200) that is normal to solar (or other) irradiance is referred to as the “optical aperture” for purposes herein. In one non-limiting example, a reflector array has overall dimension of two-hundred millimeters by two-hundred sixty-two millimeters (200 mm×262 mm) and is folded to define an angle of about forty degrees. Such an exemplary reflector array would be defined by an optical aperture of about two-hundred millimeters by about two-hundred millimeters (200 mm×200 mm) and a depth-wise dimension D2 of about one-hundred seventy millimeters (170 mm). Other examples can also be defined and used having respectively varying dimensions and folding angles.

### Illustrative Solar Device

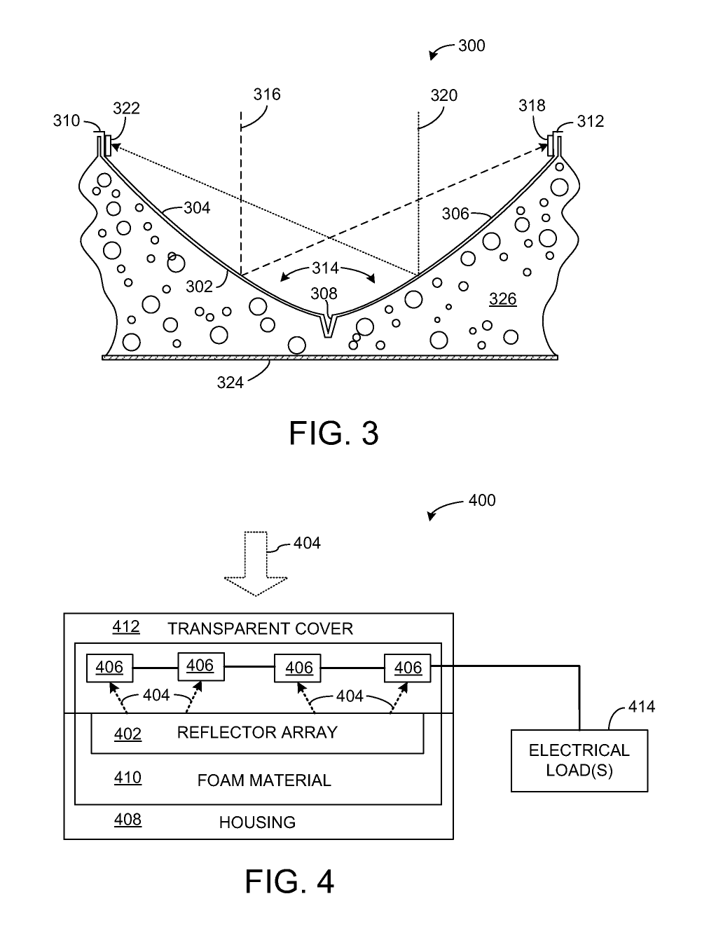

Reference is now made to FIG. 3, which depicts a sectional view of a solar device 300 according to the present teachings. The solar device 300 is illustrative and non-limiting in nature. Thus, other devices, apparatus and systems are contemplated by the present teachings.

The solar device 300 includes a sheet material 302 that has been thermoformed to define a light concentrator 304, a light concentrator 306, a lower hinge 308 and respective upper hinges 310 and 312. The sheet material 302 was thermoformed in an initial configuration defined by a generally flattened depth-wise dimension, and then folded into the operable configuration as depicted. Such folding or manipulation of the sheet material 302 is performed by way of the respective lower and upper hinges 308, 310 and 312. In one example, the sheet material 302 is a portion of the reflector array 200.

The solar device 300 also includes a reflective surface treatment or metalized film 314 born by the sheet material 302. Each of the light concentrators 304 and 306 is defined by a surface curvature being parabolic or semi-parabolic in cross-section. The light concentrator 304 is configured to concentrate incident photonic energy 316 onto a target entity 318. In one example, the target entity 318 is a photovoltaic cell configured to derive electrical energy by direct conversion of photonic energy (e.g., sunlight). Other kinds of target entities 318 can also be used. The target entity 318 is supported on the upper hinge 312. Thus, the upper hinge 312 defines or is about coincident with target location defined by the surface curvature, reflectivity and angular orientation of the light concentrator 304.

In turn, the light concentrator 306 is configured to concentrate incident photonic energy 320 onto a target entity 322. In one example, the target entity 322 is a photovoltaic cell. Other target entities can also be used. The target entity 322 is supported on the upper hinge 310. That is, the upper hinge 310 defines or is about coincident with a target location defined by the surface curvature, reflectivity and angular orientation of the light concentrator 306.

The solar device 300 also includes a housing 324. The housing can be formed from metal, plastic, fiberglass, and so on. Other suitable materials can also be used. The housing 324 is generally box-like in shape and is disposed about the underside of the sheet material 302.

The solar device further includes a foam material 326. The foam material 326 can be any suitable foam that cures to a solid phase and is characterized by a suitable structural rigidity. In one embodiment, the foam material 326 is defined by a closed-cell polyurethane foam characterized by a weight density in the range of about one-point-five to about forty pounds per cubic foot (i.e., about 1.5 Lb/Ft³ to about 40 Lb/Ft³). Other suitable foam materials 326 can also be used.

In one example, the foam material 326 is introduced into an interstitial space between the sheet material 302 and the housing 324 in a fluid-like state. The foam material 326 then expands into continuous supportive contact with the backside of the sheet material 302 and cures to a solid phase such that the operable configuration is maintained. In another example, the foam material 326 is in a solid phase and is machined or formed in accordance with the operable configuration and is thereafter bonded to the sheet material 302. Other suitable techniques can also be used.

### Illustrative System Block Diagram

Attention is now turned to FIG. 4, which depicts a block diagram of a system 400 according to the present teachings. The system 400 is illustrative and non-limiting in nature, and other systems, devices and apparatus can be defined and used according to the present teachings. The system 400 is intended to illustrate the present teachings in a generalized format, and is neither exhaustive nor limiting in that respect.

The system 400 includes a reflector array 402. The reflector array 402 is formed from thermoplastic, stamped plastic, or another relatively thin, sheet-like material. The reflector array 402 bears a reflective surface treatment (e.g., 110) and includes respective light concentrators, upper hinges and lower hinges such that incident photonic energy 404 is concentrated onto respective targets 406.

The system 400 further includes a housing 408. The housing 408 can be formed from thermoplastic, fiberglass, metal, and so on. The housing 408 is disposed generally beneath and about a backside aspect of the reflector array 402. The system 400 also includes a foam material 410 disposed between and in contact with the reflector array 402 and the housing 408. In one example, the foam material 410 is formed independently and is disposed in place during assembly of the system 400. In another example, the foam material 410 is injected between the reflector array 402 and the housing 408 and expands into contact therewith, curing to a solidified state in place. The foam material 410 is characterized by a structural rigidity when solid that serves to maintain the desired operable configuration of the reflector array 402 during normal operation. In yet another example, the foam material 410 is supplemented with or replaced by a support structure (e.g., framework or scaffolding) to support the reflector array 402 in an operable configuration.

The system 400 also includes a transparent cover 412. The transparent cover 412 can be formed from glass, plastic, acrylic, or another suitable material. The transparent cover 412 protects the reflector array 402 against potentially damaging environmental factors such as snow, rain, wind blown dust and so on during normal use.

The system 400 also includes a plurality of target entities 406 as introduced above. Each of the target entities 406 is respectively defined by a photovoltaic cell. Other suitable target entities 406 can also be used in other examples. Each of the target entities 406 is disposed to receive concentrated photonic energy 404 from a respective light concentrator of the reflector array 402. As such, each of the target entities 406 is configured to operate in accordance with its own specific characteristics.

The system 400 further includes an electrical load 414 coupled to receive electrical energy from the targets 406. Non-limiting examples of the electrical load 414 a radio transceiver, a computer, a global-positioning signal (GPS) receiver, a power supply, a storage battery, and so on. Other load devices can also be used. In another example, each of the target entities 406 is a fluid filled conduit (or a respective portion of a continuous such conduit) that absorbs thermal energy from the photonic energy 404 concentrated thereon. In such an alternative example, the load device (e.g., 414) is defined by a thermal load coupled to receive the heated fluid from the target entities 406.

The system 400 depicts the targets 406 as being disposed within the protective scope of the transparent cover 412. However, it is to be understood that other suitable configurations can be used respectively including one or more target entities 406 disposed outside of (i.e., remote from) the transparent cover 412. In still other examples, the transparent cover 412 is omitted altogether,

### Illustrative Method

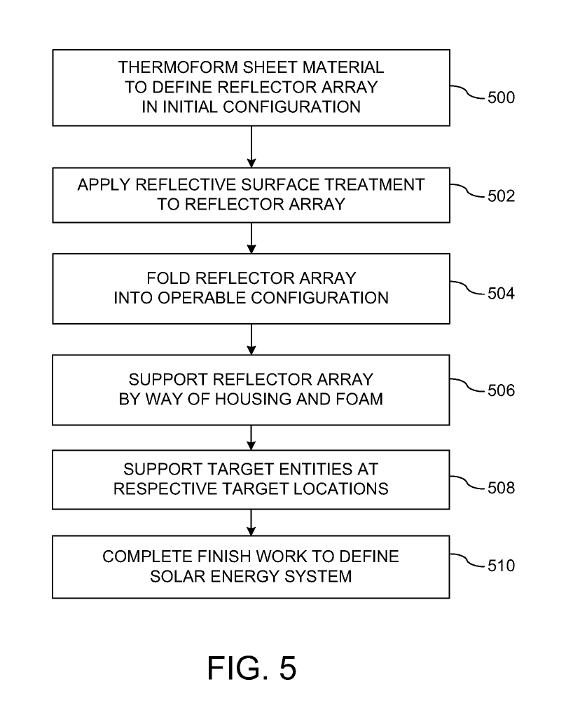

Reference is now made to FIG. 5, which depicts a flow diagram of a method according to another example of the present teachings. The method of FIG. 5 includes particular steps and proceeds in a particular order of execution. However, it is to be understood that other respective methods including other steps, omitting one or more of the depicted steps, or proceeding in other orders of execution can also be used. Thus, the method of FIG. 5 is illustrative and non-limiting with respect to the present teachings. Reference is also made to FIGS. 2A-2B, 3 and 4 in the interest of understanding the method of FIG. 5.

At 500, a reflector array is formed from thermoplastic. For purposes of a present illustration, a thermoplastic sheet material 202 is used to form a reflector array 200 having four light concentrators 208, and three upper hinges 204 and two lower hinges 206. The reflector array 200 is thermoformed in an initial configuration such that surface deformations of the thermoplastic are minimized or prevented.

At 502, a reflective surface treatment is applied to the reflector array. For purposes of the present example, a layer of aluminum and an over-coating of silicon dioxide are applied to the reflector array 200 to define a reflective surface treatment 210. The reflective surface 210 treatment can be of sufficient thickness to fully mitigate any detrimental effects due to minor surface deformations resulting from the thermoforming at step 500 above. In an alternative example, a reflective metalized film 210 is bonded to the sheet material 202.

At 504, the reflector array is folded into an operable configuration. For purposes of the present example, the reflector array 200 is folded or manipulated by way of the upper and lower hinges 204 and 206 into an operable configuration. This operable configuration is such that the target locations defined by the light concentrators 208 are coincident with respective locations along the upper hinges 204.

At 506, the reflector array is supported by way of a housing and foam material. For purposes of the present example, the reflector array 200, being folded into the operable configuration, is disposed within a box-like housing 324. A foam material 326 is then introduced into an interstitial space between the reflector array 200 and the housing 324. The foam expands into continuous supportive contact with the reflector array 200 and the housing and solidifies in place.

At 508, target entities are supported at respective target locations. For purposes of the present example, photovoltaic cells 318, 322 are disposed at respective target locations defined by the light concentrators 208. These target locations are coincident with respective locations along the upper hinges 204.

At 510, finish work is completed to define a solar energy system. For purposes of the present example, the photovoltaic cells 318, 322 are electrically coupled to an electrical load 414, such as a computer. Additionally, a transparent cover 412 is disposed over and bonded to the housing 324 such that the reflector array 200 is protected from environmental elements. Other finish steps can be performed as desired, such that a solar energy system 400 is defined.

In general and without limitation, the present teachings contemplate solar energy devices and systems and methods of their use. A reflector array is formed from a relatively thin plastic, thermoplastic or another suitable material. The reflector array is molded or shaped by way of thermoforming, stamping, or other techniques such that a monolithic entity having an initial configuration is formed. Surface deformations such as “stretch marks” and the like are minimized or eliminated by forming the reflector array in an initial configuration having a generally minimized overall depth-wise dimension.

The reflector array includes a plurality of light concentrators and respective upper and lower hinges. Each of the light concentrators is in turn defined by a surface contour. Non-limiting examples of such surface contours include parabolic troughs, segmented parabolic concentrators, double-curvature concentrators or “dish-like” shapes, and so on. Other suitable surface contours can also be used. A reflector array can include any suitable number of distinct light concentrators arranged in any suitable “X-by-Y” configuration or count.

A reflective surface treatment is applied, deposited, formed or bonded to the reflector array. This surface treatment can be defined by or includes a reflective metal or other material, a protective over-coating such as silicon dioxide, and so on. Alternatively, a reflective metalized film can be bonded to the reflector array. The reflective surface treatment is such that photonic energy incident to a particular light concentrator is concentrated onto a target location defined by the respective surface curvature thereof.

For example, a single parabolic light concentrator is configured to concentrate photonic energy onto an elongated strip-like target location or region. In another example, a double-curvature light concentrator is configured to concentrate photonic energy onto a spot-like target location or region.

The reflector array is then folded or manipulated from the initial configuration into an operable configuration. Such manipulation corresponds to a general increase in the overall depth-wise dimension of the reflector array. In some examples, the target locations defined by the light concentrators are made coincident with the upper hinge features in accordance with the folding.

A housing is formed from a material such as thermoplastic, fiberglass, metal or another suitable material. The housing is shaped to be disposed about a backside portion of the reflector array in the operable configuration. In some examples, an interstitial volume is defined between the reflector array and the housing that is filled (or nearly so) with a foam material. The foam material can be introduced as expanding foam that cure or hardens in place. Alternatively, the foam material can be pre-formed as a separate and distinct entity that is placed into the interstitial volume during assembly. The housing and foam material collectively define a support structure for the reflector array in the operable configuration.

The foam material is in continuous supportive contact with at least a majority portion of the backside of the reflector array, as well as the inside wall surfaces of the housing. Structural rigidity of the foam material functions to resist bending, folding, twisting or other deformation of the reflector array or housing when the finished assemblage is subject to environment forces such as wind, snow, rain, and so on.

Energy absorbing or energy conversion target entities are secured in place at the respective light concentrating target locations defined by the light concentrators of the reflector array. Such target entities can include photovoltaic cells, thermal energy absorbing fluid conduits, and so on. The target entities can be defined by respective operating characteristics. Electrical and/or thermal loads can be coupled to receive energy from the target entities during typical normal use.

A transparent cover can be formed from any suitable material and joined to the housing so as to protect the reflector array. The transparent cover can, in some examples, function to support the one or more target entities at the respective target locations. The transparent cover can also be bonded to the housing about a periphery thereof. Such bonding or joining can be permanent or the transparent cover can be removably joined by way of mechanical fasteners, and so on.

In general, the foregoing description is intended to be illustrative and not restrictive. Many embodiments and applications other than the examples provided would be apparent to those of skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

What is claimed is:

1. A method, comprising:
forming a sheet material to define a reflector array, the reflector array characterized by one or more hinges and a plurality of light concentrators;
folding the reflector array from an initial configuration to an operable configuration by way of the hinges; and
supporting the reflector array in the operable configuration by way of a support structure.

2. The method according to claim 1, the forming the sheet material including thermoforming a plastic material to define the reflector array.

3. The method according to claim 1, the forming the sheet material including stamping a plastic material to define the reflector array.

4. The method according to claim 1 further comprising applying at least a reflective surface treatment, or a reflective metalized film to at least some of the sheet material.

5. The method according to claim 1, the one or more hinges including an upper hinge and a lower hinge.

6. The method according to claim 1, each of the light concentrators defining a target location.

7. The method according to claim 6, the one or more hinges including an upper hinge, at least some of the target locations being about coincident with respective areas of the upper hinge.

8. The method according to claim 6 further comprising disposing a photovoltaic cell at each of the target locations.

9. The method according to claim 1, the support structure including at least a housing, or a foam material.

10. The method according to claim 1, the initial configuration defined by a depth-wise dimension that is lesser than that of the operable configuration.

11. A system, comprising:
a monolithic structure defining one or more hinges and a plurality of light concentrators, the monolithic structure formed from a sheet material;
a reflective material supported by the monolithic structure coincident with at east the light concentrators such that a solar array is defined;
a structure to support the solar array in an operable configuration, the operable configuration characterized by a folding of the monolithic structure at the one or more hinges.

12. The system according to claim 11, each of the light concentrators defined by a surface contour configured to concentrate incident photonic energy onto a spot-like target location.

13. The system according to claim 11, each of the light concentrators defined by a surface contour configured to concentrate incident photonic energy onto a strip-like target location.

14. The system according to claim 11, the solar array defining a plurality of parallel troughs.

15. The system according to claim 11, structure including at least a housing, or a foam material.

16. The system according to claim 11 further comprising a plurality of photovoltaic cells supported so as to receive concentrated photonic energy from the light concentrators.
